(19) United States
(12) Patent Application Publication
(10) Pub. No.: US 2008/0212265 A1
(43) Pub. Date: Sep. 4, 2008

(54) Switchgear Cabinet for Accommodating Electronic Plug-In Modules with a Heat Exchanger

(76) Inventors: Paul Mazura, Karlsbad (DE); Adam Pawlowski, Waldbronn-Reichenbach (DE)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(21) Appl. No.: 12/017,427

(22) Filed: Jan. 22, 2008

(30) Foreign Application Priority Data
Jan. 23, 2007 (EP) EP 07 001 356.0

(51) Int. Cl. H05K 7/20

(52) U.S. Cl. 361/678; 361/696

(57) ABSTRACT

The present invention pertains to a switchgear cabinet for accommodating electronic plug-in modules with an interior in which the heat-generating plug-in modules can be inserted one on top of another, a roof area arranged above the interior and a base arranged underneath the interior and that forms a base area. The switchgear cabinet furthermore comprises an air channel that is arranged to the side of the interior and connects the roof area to the base area. A closed cooling circuit within the switchgear cabinet serves for carrying off the heat generated by the plug-in modules. A fan arranged in the roof area takes in air from the interior and blows this air into the air channel. The heated air from the air channel flows around a heat exchanger arranged in the base in such a way that the air is cooled and the thereby produced cooling air is admitted into the interior from below and flows through this interior vertically upwards.

### TECHNICAL FIELD OF THE INVENTION

The present invention pertains to a switchgear cabinet for accommodating electronic plug-in modules with a heat exchanger.

### BACKGROUND

Switchgear cabinets are typically fitted with a series of plug-in modules that are arranged one on top of another in several layers. The plug-in modules are inserted into guide rails provided for this purpose and aligned vertically. The adjacent plug-in modules are separated from one another in such a way that the heat generated by the modules can be transferred to their surroundings. The transferred heat is carried off by the air circulating between the modules.

The waste heat of the individual modules increases due to the escalating power of electronic components, as well as the continuously increasing clock frequencies and the utilization of high-speed processors on the plug-in modules. Consequently, the waste heat being generated can no longer be carried off merely by perforating the doors and/or side walls of the cabinets, as well as their bottoms and roofs. The cabinets are provided with a closed cover, particularly in certain applications in which the electric leakproofness of the switchgear cabinet, as well as its shielding effect and shielding properties, are especially important. A transfer of heat to the surroundings of the switchgear cabinet is not possible in this case. Consequently, cooling systems with air circulation are provided which are intended to carry off the heat being generated with the aid of fans respectively arranged in the side walls or in the roof and bottom of the switchgear cabinet.

A liquid cooling system may also be used in individual instances. In this case, the individual modules are fitted with cooling arrangements that are connected to a fluid cooling circuit. Plug-in modules of this type are known, for example, from DE 20 2004 010 204.8.

Switchgear cabinets are furthermore equipped with heat exchangers that cool the air. The waste heat generated by the individual plug-in modules is conveyed through and cooled by the heat exchanger so that a closed cooling circuit can be realized. The heat exchanger may be realized, for example, in the form of an air/water heat exchanger that is supplied with cooling water. Conventional heat exchangers and air/water heat exchangers are mounted on the roof of the switchgear cabinet or in the outer region of a side wall and on the rear door. For certain applications, they are also realized in the form of a module positioned in the lower region of the switchgear cabinet.

However, if the heat exchanger is arranged on a side wall, several switchgear cabinets can be arranged only, if at all, adjacent to one another to a limited extent. The available installation space for the cabinets is not optimally utilized. If an air/water heat exchanger is arranged on the roof of the cabinet, escaping water or drops of condensation water can lead to damage to the electronic plug-in modules.

In order to avoid the risk of damage to the electronic plug-in modules by dripping water, the heat exchangers are arranged underneath or in the base of the switchgear cabinet. A switchgear cabinet of this type with an air/water heat exchanger arranged in its base is known from Japanese publication JP08125372A. In the proposed switchgear cabinet, the base contains an arrangement of two heat exchangers each of which is combined with a fan. Part of the cooling air generated by the heat exchanger is mixed with the warm air supplied from the roof of the switchgear cabinet via an air channel before the mixed air is fed to the heat exchanger. The other part of the cooling air is directly fed to the switchgear cabinet in order to cool the electronic modules. The airflow within the switchgear cabinet is improved by arranging a fan for promoting the vertical airflow to the roof of the switchgear cabinet approximately in the center of the cabinet between two module planes that lie one on top of the other.

The cooling unit consisting of the heat exchanger and the fan is very costly. It is intended to avoid icing of the heat exchanger unit. However, the air conduction within the switchgear cabinet is poor because part of the airflow is once again deflected toward the air inlet of the heat exchanger. This is allegedly compensated by the fan that is arranged centrally in the interior of the switchgear cabinet. If servicing is required, it is difficult to replace the fan arranged in the interior because it is necessary to open the region containing the electronic modules, so that the electronic units must invariably be switched off.

### SUMMARY OF THE INVENTION

The present invention relates to a switchgear cabinet for electronic modules with a heat exchanger, in which the modules cannot be damaged by dripping water.

In accordance with a preferred embodiment of the invention, the switchgear cabinet for accommodating electronic plug-in modules comprises an interior, in which the heat-generating plug-in modules are arranged one on top of another, a roof area arranged above the interior and a base forming a base area that is connected to and situated underneath the interior. The interior and the base area are separated by a bottom of the interior, wherein the bottom features an opening for the air flowing through both of these spaces. The roof area and the base area are connected by at least one air channel that is arranged laterally of the interior. A fan arranged in the roof area takes in air from the interior and blows this air into the base area through the air channel. The heated air flowing into the base area from the air channel flows around a heat exchanger arranged in the base area of the cabinet so that the air is cooled in the heat exchanger. The cooling air thereby produced is introduced into the interior of the switchgear cabinet from below and flows through the interior vertically upward. A closed cooling circuit for carrying off the heat generated by the plug-in modules is thus created in the switchgear cabinet.

The inventive switchgear cabinet in its preferred form has the advantage that dripping water or condensation water being formed on the heat exchanger cannot damage the electronic plug-in modules because the heat exchanger is positioned underneath the modules. This simultaneously improves the accessibility of the heat exchanger because the base area can advantageously be accessed separately. If the heat exchanger is damaged or fails, it can be removed from the base of the cabinet without having to access the switchgear cabinet, particularly its interior containing the electronic plug-in modules. The modules or devices thereby no longer must be switched off. The base may be realized, for example, in the form of a drawer such that the accessibility of the heat exchanger is further improved.

The fan arranged in the roof area of the switchgear cabinet significantly improves the airflow through the switchgear cabinet. The circulation within the switchgear cabinet is optimized. The warm air taken in is blown directly into the air channel of the switchgear cabinet and fed to the heat exchanger without creating an air back-up or reducing the airflow. The formation of condensate on the roof of the switchgear cabinet is avoided because the heated air immediately flows into the air channel and does not precipitate in the roof area.

The formation of condensate above the plug-in modules and therefore the possible damage to the plug-in modules due to dripping moisture are easily and reliably prevented due to the combination of the heat exchanger arranged in the base and the fan arranged in the roof area.

In accordance with another aspect of a preferred embodiment of a switchgear cabinet, it may be advantageous to position several air channels in the switchgear cabinet in order to return the heated air from the roof area to the heat exchanger positioned in the base. This will improve air conduction within the switchgear cabinet. The air channels may be realized on several side walls. An air channel may be (additionally) arranged in the door and/or the rear wall. If the switchgear cabinet features a front door and a rear door, it is possible to arrange in one or both doors one or more air channels that preferably extend parallel to one another.

The air channels on the side wall are preferably spaced apart from one another in such a way that each channel is provided with a larger wall surface area that may also fulfill the function of a heat exchanger, particularly if the air flowing through the channel and the air in the interior around the air channel have a certain temperature difference.

If the air temperature in the air channel is lower than the ambient temperature, the surroundings around the air channel are cooled by the downwardly flowing air in the air channel. In this case, the air channel acts like another heat exchanger and along with the cooling air flowing through the interior cools the plug-in modules.

If several air channels are arranged adjacent to one another on one side of the interior of the switchgear cabinet, the cross section of each individual air channel preferably is sufficiently large to allow the air to flow from the roof area into the base area without friction and to prevent any air back-up. The airflow preferably is laminar and free of turbulences.

The following options may be considered for realizing the air channel or air channels arranged to the side of the interior.

1. The air channel is preferably arranged or formed on an outer wall of the switchgear cabinet. This embodiment is particularly preferred in instances in which the interior itself does not feature any side walls or similar large-surface peripheral elements. In this case, the air channel is preferably formed on the inside of the outer wall of the switchgear cabinet and points toward the interior of the switchgear cabinet. The air channel simultaneously acts as a heat exchanger since the temperature of the air flowing through the air channel is usually lower than that of the air in the immediate vicinity of the plug-in modules. This results in additional cooling of the plug-in modules so that the efficiency of the entire cooling circuit is increased.

2. If the interior of the switchgear cabinet features additional side walls, the air channel may also be realized on the side wall of the interior. The air channel may be selectively arranged on the inside and/or on the outside of the outer wall.

3. In instances in which the interior, as well as the switchgear cabinet, features a lateral wall, for example, if stricter requirements with respect to the electric shielding effect apply, the intermediate space between the side wall of the interior and the outer wall of the switchgear cabinet may be used as an air channel. This intermediate space is preferably divided in the vertical direction such that several adjacent air channels are formed.

The partitions may be realized, for example, in the form of separation plates and preferably are rigidly connected to both walls, particularly by means of welding, so that they can simultaneously serve for reinforcing the cabinet and the side walls, respectively.

It is particularly preferred that the air channel be formed by reinforcing elements of the interior wall. These reinforcing elements may consist, for example, of trapezoidal or rectangular sheet metal elements and are connected to the wall so that they increase its rigidity. The connection may consist of either a separable connection that is produced, for example, with the aid of several screws, or of a rigid or integral connection, for example, if the sheet metal and the wall are connected by means of rolling or welding. The connection between the reinforcing sheet metal elements and the wall is preferably realized over such a large surface that the air cannot escape from the air channel at or between the connecting points and thus is conveyed through the air channel in its entirety.

If the air channels are realized in doors, arrangement on the outer wall of the door proves particularly advantageous. In this case, the interior is directly accessible after the door is opened.

In a preferred embodiment, the fan in the roof area of the switchgear cabinet is realized in the form of a radial fan. On its underside, the radial fan features an air inlet that is directed toward the interior of the switchgear cabinet. An air outlet of the radial fan is oriented in the direction of the air channel so that the air taken in from the interior is directly moved toward the air channel.

The fan preferably features at least two lateral air outlets that are directed toward at least two air channels. If one air channel is arranged on each of the opposing side walls, it is particularly preferred that a radial fan with two opposing air outlets that are respectively oriented toward the side walls be used. If air channels are provided on all side walls and on the door, the radial fan preferably is laterally open so that the air taken in is blown radially outwards in all directions in order to flow into the corresponding air channels.

In another preferred embodiment of the inventive switchgear cabinet, several fans are arranged in the roof area of the switchgear cabinet. The fans are preferably evenly distributed over the base area of the interior. It is particularly preferred to use four or nine fans arranged in a rectangular or square configuration. The use of several small fans has the advantage that a sufficiently high air throughput is still realized if one of the fans fails, so that overheating of the electronic plug-in modules can be reliably prevented. In addition, the structural height of small fans is frequently reduced, such that the switchgear cabinet usually can also be easily retrofitted with such fans.

### BRIEF DESCRIPTION OF THE DRAWINGS

FIG. 1, a front section through a switchgear cabinet for accommodating plug-in modules;

FIG. 2, a side view of the switchgear cabinet illustrated in FIG. 1;

FIG. 3a, a top view of the switchgear cabinet illustrated in FIG. 1 with a fan arranged in the roof area of the switchgear cabinet;

FIG. 3b, an alternative embodiment of a switchgear cabinet with two fans arranged in the roof area, and

FIG. 4, a section through a side wall of the switchgear cabinet illustrated in FIG. 1.

### DETAILED DESCRIPTION OF EXEMPLARY EMBODIMENTS

In the following description, like numbers refer to like elements.

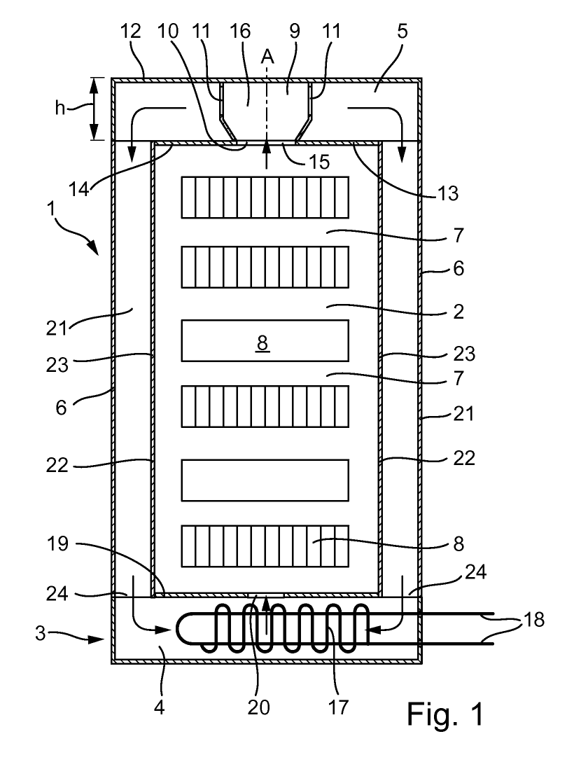

FIG. 1 shows a section through a switchgear cabinet 1 for accommodating electronic plug-in modules. The switchgear cabinet 1 comprises an interior 2, a base 3 arranged underneath the interior 2 and that forms a base area 4 and a roof area 5 arranged above the interior 2. Two vertically extending outer walls 6 form the periphery of the switchgear cabinet 1.

Plug-in modules 8 are arranged in the interior 2 in several planes 7 that are arranged one on top of another. The plug-in modules 8 of one plane 7 are separated from one another in such a way that air can vertically flow between the modules. On their front side, the plug-in modules 8 respectively feature front plates that end flush with one another. The plug-in modules 8 are displaceably supported in the individual planes 7 in horizontally extending guide rails.

The roof area 5 above the interior 2 contains a fan 9 that takes in air from the interior 2. The fan 9 features an air inlet 10 that is oriented toward the interior 2. On its outer sides, the fan features two opposing air outlets 11 that are oriented toward the outer walls 6 of the switchgear cabinet 1. The fan 9 is preferably realized in the form of a radial fan 16 and features several fan blades that rotate about a vertically extending longitudinal axis A.

The upper periphery of the roof area 5 is formed by a roof 12, and the lower periphery of the roof area is formed by a cover plate 13 that creates a partition wall 14 between the roof area 5 and the interior 2 and separates these two areas from one another. This arrangement with the partition wall 14 provides the advantage that the top of the interior 2 is also closed when the roof area 5 is opened, e.g., when the roof 12 is removed in order to perform repairs or maintenance on the fan 9.

In this preferred embodiment, in which the interior 2 and the roof area 5 are separated from one another by a partition wall 14, the partition wall 14 advantageously features an air through-opening 15, above which the fan 9 is arranged. The through-opening 15 is realized in such a way that it corresponds to the air inlet 10. The air inlet 10 is aligned with and adjoins the through-opening 15 such that air is taken in only from the interior 2 and not from the roof area 5. Alternatively, an air connection may be provided between the air inlet 10 and the through-opening 15 if the air inlet 10 is separated from the partition wall 14. This is the reason that the through-opening 15 is advantageously realized circularly, wherein the center of the through-opening 15 is aligned with the axis A of the radial fan 16.

The use of a radial fan 16 proves particularly advantageous because the radial fan causes a deflection of the airflow by 90°. The entire available roof height h of the roof area 5 can thereby be utilized. However, the roof height may also be adapted to the relatively small structural height of the radial fan 16 so that the interior 2 is enlarged if the cabinet has a constant height.

An axial fan or a diagonal fan may of course also be used instead of a radial fan 16. In this case, the air that is vertically taken in from the interior 2 must be deflected in the roof area 5 in order to convey this air to the outer walls 6.

It is advantageous that the roof area 5 is accessible from outside without having to open the interior 2 of the switchgear cabinet 1. The plug-in modules 8 thereby also remain operative when the roof area 5 is opened, for example, in order to exchange or repair the fan 9. The roof area is preferably accessible on the front side and/or the rear side of the cabinet.

On its lower end, the interior 2 advantageously features a bottom 19 that separates the interior from the base area 4. The bottom 19 is permeable to cooling air. For this purpose, it preferably features at least one opening 20 through which the cooling air can be admitted into the interior 2 from the base area 4. An air/water heat exchanger 17 arranged in the base area 4 is connected to a cold water circuit via two water connections 18. The heat exchanger 17 preferably is positioned directly underneath the opening 20. It would also be possible to provide several openings instead of a single opening 20. For example, the bottom 19 may be perforated and feature a large number of smaller openings, preferably round or square holes. The number and the size of the openings 20, as well as their design and shape, are defined by the corresponding fluidic optimization. The openings 20 are realized in such a way that no turbulent flow is created on the edges of the openings 20.

In a preferred embodiment, the air inlet opening 20 in the bottom 19 of the interior 2 may be realized so that it nearly occupies the entire surface of the bottom 19 and a frame-like arrangement of the bottom is formed. However, it is particularly preferred that the opening 20 in the bottom 19 be adapted to the heat exchanger 17 in the base area 4 so that the entirety of the cooling air initially flows around the heat exchanger 17 before it is admitted into the interior 2 through the opening 20.

The outer walls 6 feature an air channel 21 that extends vertically and connects the base area 4 to the roof area 5. The air channel 21 is formed by the outer wall 6 and a reinforcing element 23 that stabilizes and reinforces the outer wall 6. The reinforcing element 23 is connected to the outer wall 6 in such a way that a tight lateral seal is formed and the airflow is conveyed within the air channel 21.

The heat generated in the interior 2 by the plug-in modules 8 is transferred to the surroundings in the interior 2. The warm air thereby generated is taken in by the radial fan 16 in the roof area 5 and blown out of the air outlets 11 in such a way that it is deflected to the air channels 21 in the outer walls 6 along the roof 12. The warm air then flows downward from the roof area 5 through the air channels 21 on the outer walls 6 and is admitted into the base area 4 through air channel outlet openings 24. The warm air is conveyed past the heat exchanger 17 in the base area so that it is cooled. The cooling air thereby generated is conveyed into the interior 2 through the openings 20. Convection is promoted by the fan 9 in the roof area 5 so that the cooling air flows through the interior 2 vertically upward in the direction of the roof area 5 while it cools the plug-in modules 8.

Consequently, a closed cooling air circuit is formed that carries off the heat generated by the plug-in modules 8. The inner walls 22 of the air channels 21 that are formed by the reinforcing elements 23 also serve as heat exchangers. The inner wall 22 additionally cools the plug-in modules 8 since the air conveyed from the roof area 5 to the base area 4 in the air channels 21 is cooler than the air that is directly heated by the plug-in modules 8.

FIG. 1 shows two decisive advantages of this embodiment. First, condensation water forming on the heat exchanger 17 drips downward in the base area 4 and cannot reach the plug-in modules 8 or other electronic units arranged in the interior 2. Second, the warm air conveyed into the roof area 5 is reliably moved into the air channel 21 by the fan 9. Backed-up air in the roof area 5 is thereby prevented so that the formation of condensate on the roof 12 is easily and reliably prevented. Furthermore, the air channel 21 also serves as a heat exchanger and contributes to the cooling of the interior 2.

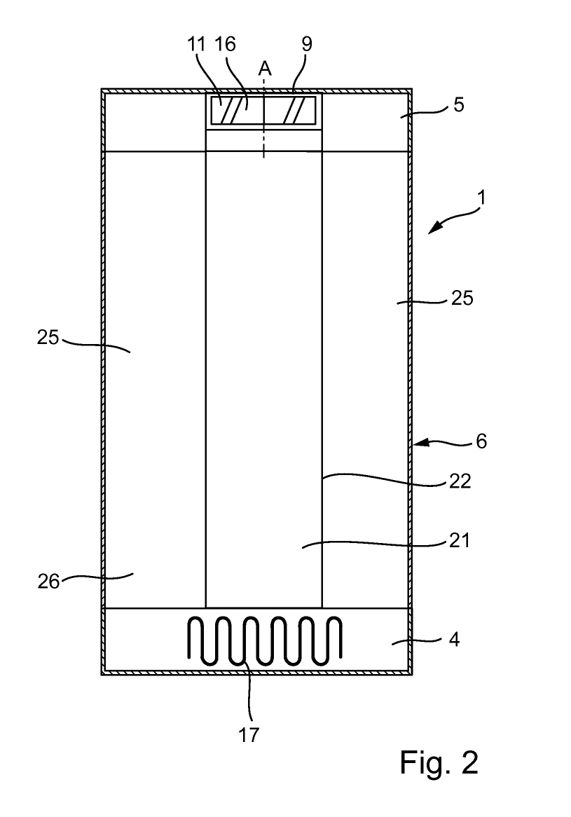

FIG. 2 shows a lateral section through the air channel 21 on the outer wall 6 of the switchgear cabinet 1. The air channel 21 that extends vertically in the center of the outer wall 6 is formed by the outer wall 6 and an inner wall 22. A region 25 for accommodating the wiring for the plug-in modules 8 is respectively arranged on the outer wall 6 to both sides of the air channel 21. The regions 25 are respectively realized in the form of a cable channel 26, in which the signal and supply lines run. The two cable channels 26 also make it possible to separate the supply lines from the signal lines.

The radial fan 16 is arranged above the air channel 21 in the roof area 5. Its axis of rotation is aligned with the central axis of the air channel 21. The radial fan 16 features an air outlet 11 that is oriented toward the air channel 21. The warm air taken in by the fan is blown toward the air channel 21 and then conveyed vertically downward therein.

FIG. 2 also shows that the roof area 5 and the interior 2 are separated from one another by the partition wall 14. The partition wall 14 features a (not-shown) through-opening 15 that is aligned with and adjoins the air inlet of the radial fan 16. The air taken in from the interior 2 is thus conveyed through the radial fan 16 in its entirety. In another preferred embodiment, the partition wall 14 may be inclined so that is slightly descends toward the outer sides. This is possible, in particular, if the radial fan 16 used has a smaller structural height than the height of the roof area 5. The airflow and the air circulation in the interior 2 are additionally optimized with such an inclined partition wall 14.

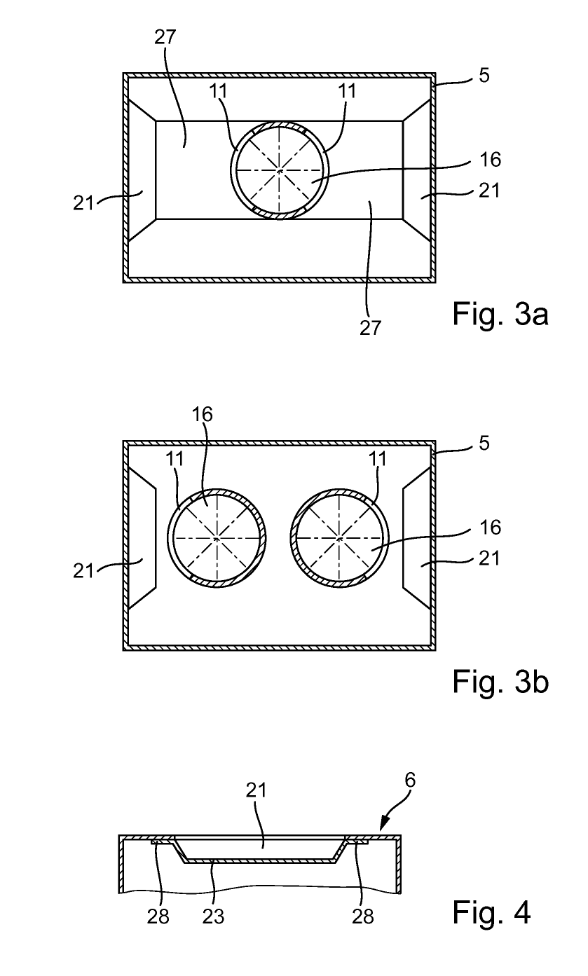

FIGS. 3a and 3b show a top view of the roof area 5 with the roof 12 removed. FIG. 3a shows an embodiment in which a radial fan 16 is used. The warm air taken in by the fan 9 from below is blown out of the two air outlets 11 and conveyed in the direction of the two opposing air channels 21. In this case, the air is conveyed in an air conduction channel 27 that connects the radial fan 16 to the air channels 21. The fan 9 is arranged centrally in the air conduction channel 27. The air is exclusively conveyed through the air conduction channel 27 in the roof area 5 so that an optimal airflow is formed and any formation of condensate in the roof is prevented.

FIG. 3b shows an embodiment in which two radial fans 16 are arranged in the roof area 5. Each fan is arranged in the vicinity of the corresponding air channel 21. Each air outlet 11 of the radial fans 16 is directed toward an air channel 21. The air taken in from the interior 2 is directly blown into the air channel 21 and moved in the direction of the base area 4. An air conduction channel 27 between the fan 9 and the air channel 21 may also be realized in the roof.

The air outlet 11 is adapted to the air channel 21. The dimensions of the air outlet 11 are dependent on the distance of the radial fan 16 from the air channel 21 and on the width of the air channel 21. In the example shown in FIG. 3b, the width of the air outlet 11 approximately corresponds to a quadrant. The air outlet opening is correspondingly smaller when narrower air channels are used; this applies analogously if the radial fan 16 is separated from the air channel 21 by a greater distance.

In addition to the embodiment according to FIG. 3b that features two radial fans, it would also be possible to provide several smaller fans. These smaller fans are preferably arranged in a square or rectangular configuration. An air conduction channel can be eliminated in this case.

FIG. 4 shows a cross section through the outer wall 6. This figure clearly shows the air channel 21 that is formed by the reinforcing element 23 and the outer wall 6. The reinforcing element 23 consists of a sheet metal element that extends over the entire height of the outer wall 6 and the contact flanges 28 of which lie parallel to the outer wall 6. The reinforcing element 23 is welded to the inner side of the outer wall 6 at the contact flanges 28. The rigidity of the outer wall 6 is increased in this way. This has the advantage that relatively thin sheet metal can be used for the outer wall 6. A corresponding connection must be chosen depending on the material of the outer wall and of the reinforcing element. A permanent connection can be produced, for example, by means of bonding or with rivets or screws. It is of course also possible to choose other connecting and mounting methods known to a person skilled in the art.

The foregoing description is of an exemplary and preferred embodiments employing at least in part certain teachings of the invention. The invention, as defined by the appended claims, is not limited to the described embodiments. Alterations and modifications to the disclosed embodiments may be made without departing from the invention. The meaning of the terms used in this specification are, unless expressly stated otherwise, intended to have ordinary and customary meaning and are not intended to be limited to the details of the illustrated structures or the disclosed embodiments.

What is claimed is:

1. A switchgear cabinet for accommodating electronic plug-in modules, comprising
an interior, into which the plug-in modules can be inserted one on top of another;
a roof area that is arranged above the interior;
a base with a base area that is arranged underneath the interior and connected to the interior;
an air channel that is arranged to the side of the interior and connects the roof area to the base area;
a fan that is arranged in the roof area and takes in cooling air from the interior, wherein said fan conveys this air into the base area through the air channel so that a closed cooling air circuit for carrying off the heat generated by the plug-in modules from the interior is formed, and wherein the cooling air flows vertically through the interior from the bottom toward the top; and
a heat exchanger that is arranged in the base area and cools the cooling air.

2. The switchgear cabinet according to claim 1, further comprising a bottom provided between the interior and the base area that is permeable to cooling air.

3. The switchgear cabinet according to claim 2, wherein the interior and the roof area are separated from one another by a partition wall, and the partition wall features a passage opening, above which the fan is arranged.

4. The switchgear cabinet according to claim 2 wherein the air channel is formed on a side wall of the interior.

5. The switchgear cabinet according to claim 2, wherein the air channel is formed on an outer wall of the switchgear cabinet.

6. The switchgear cabinet according to one of claim 2, wherein the air channel is formed between the side wall of the interior and the outer wall of the switchgear cabinet.

7. The switchgear cabinet according to claim 2, wherein several air channels are realized in the switchgear cabinet.

8. The switchgear cabinet according to claim 2, wherein the fan consists of a radial fan and features a lateral air outlet, preferably at least two air outlets, that is directed toward the air channel, wherein it is particularly preferred that the radial fan be laterally open.

9. The switchgear cabinet according to claim 1, wherein the interior and the roof area are separated from one another by a partition wall and the partition wall features a passage opening, above which the fan is arranged.

10. The switchgear cabinet according to claim 9, wherein the fan features an air inlet that is connected to the passage opening in the partition wall in such a way that air is only taken in from the interior.

11. The switchgear cabinet according to claim 10 wherein the air channel is formed on a side wall of the interior.

12. The switchgear cabinet according to claim 10 wherein the air channel is formed between the side wall of the interior and the outer wall of the switchgear cabinet.

13. The switchgear cabinet according to claim 10, wherein several air channels are realized in the switchgear cabinet.

14. The switchgear cabinet according to claim 10, wherein the fan consists of a radial fan and features a lateral air outlet, preferably at least two air outlets, that is directed toward the air channel, wherein it is particularly preferred that the radial fan be laterally open.

15. The switchgear cabinet according to claim 9 wherein the air channel is formed on a side wall of the interior.

16. The switchgear cabinet according to claim 9, wherein the air channel is formed on an outer wall of the switchgear cabinet.

17. The switchgear cabinet according to claim 9 wherein the air channel is formed between the side wall of the interior and the outer wall of the switchgear cabinet.

18. The switchgear cabinet according to claim 9, wherein several air channels are realized in the switchgear cabinet.

19. The switchgear cabinet according to claim 9, wherein the fan consists of a radial fan and features a lateral air outlet, preferably at least two air outlets, that is directed toward the air channel, wherein it is particularly preferred that the radial fan be laterally open.

20. The switchgear cabinet according to claim 1 wherein the air channel is formed on a side wall of the interior.

21. The switchgear cabinet according to claim 20, wherein several air channels are realized in the switchgear cabinet.

22. The switchgear cabinet according to claim 20, wherein the air channel is formed by reinforcing elements that extend on one of the walls of the switchgear cabinet.

23. The switchgear cabinet according to claim 22, wherein several air channels are realized in the switchgear cabinet.

24. The switchgear cabinet according to claim 22, wherein the fan consists of a radial fan and features a lateral air outlet, preferably at least two air outlets, that is directed toward the air channel, wherein it is particularly preferred that the radial fan be laterally open.

25. The switchgear cabinet according to claim 20, wherein the fan consists of a radial fan and features a lateral air outlet, preferably at least two air outlets, that is directed toward the air channel, wherein it is particularly preferred that the radial fan be laterally open.

26. The switchgear cabinet according to claim 1, wherein the air channel is formed on an outer wall of the switchgear cabinet.

27. The switchgear cabinet according to claim 26, wherein the air channel is formed by reinforcing elements that extend on one of the walls of the switchgear cabinet.

28. The switchgear cabinet according to claim 26, wherein several air channels are realized in the switchgear cabinet.

29. The switchgear cabinet according to claim 26, wherein the fan consists of a radial fan and features a lateral air outlet, preferably at least two air outlets, that is directed toward the air channel, wherein it is particularly preferred that the radial fan be laterally open.

30. The switchgear cabinet according to claim 1, wherein the air channel is formed between the side wall of the interior and the outer wall of the switchgear cabinet.

31. The switchgear cabinet according to claim 30, wherein several air channels are realized in the switchgear cabinet.

32. The switchgear cabinet according to claim 30, wherein the fan consists of a radial fan and features a lateral air outlet, preferably at least two air outlets, that is directed toward the air channel, wherein it is particularly preferred that the radial fan be laterally open.

33. The switchgear cabinet according to claim 1, wherein several air channels are realized in the switchgear cabinet.

34. The switchgear cabinet according to claim 33, wherein the fan consists of a radial fan and features a lateral air outlet, preferably at least two air outlets, that is directed toward the air channel, wherein it is particularly preferred that the radial fan be laterally open.

35. The switchgear cabinet according to claim 1, wherein the fan consists of a radial fan and features a lateral air outlet, preferably at least two air outlets, that is directed toward the air channel, wherein it is particularly preferred that the radial fan be laterally open.
